(19) United States
(12) Patent Application Publication
(10) Pub. No.: US 2014/0224176 A1
(43) Pub. Date: Aug. 14, 2014

(54) MOCVD APPARATUS

(71) Applicants: Do Young Rhee, Seoul (KR); Young Sun Kim, Suwon-si (KR); Sung Tae Kim, Seoul (KR); Sang Heon Han, Suwon-si (KR); Ki Sung Kim, Suwon-si (KR)

(72) Inventors: Do Young Rhee, Seoul (KR); Young Sun Kim, Suwon-si (KR); Sung Tae Kim, Seoul (KR); Sang Heon Han, Suwon-si (KR); Ki Sung Kim, Suwon-si (KR)

(73) Assignee: SAMSUNG ELECTRONICS CO., LTD., Suwon-si, Gyeonggi-do (KR)

(21) Appl. No.: 14/124,190

(22) PCT Filed: Aug. 9, 2011
(86) PCT No.: PCT/KR2011/005772

§ 371 Date: Dec. 5, 2013

(51) Int. Cl. C30B 25/08; C30B 25/12

(52) U.S. Cl. CPC C30B 25/08; C30B 25/12
USPC 118/724; 118/730

(57) ABSTRACT

A metal-organic chemical vapor deposition (MOCVD) apparatus includes: a reaction chamber including a chamber main body forming an interior space having a certain volume and a chamber cover hermetically sealing the chamber main body to maintain air-tightness; a susceptor rotatably provided within the chamber main body and having one or more accommodation portions formed in an upper surface thereto to accommodate wafers; a cover member detachably provided on an interior surface of the chamber cover, forming a reaction space between the cover member and the susceptor, and formed by coupling a plurality of section members; and a gas supply unit supplying a reactive gas to the reaction space to allow the reactive gas to flow between the susceptor and the cover member.

### BACKGROUND OF THE INVENTION

1. Field of the Invention

The present invention relates to a metal-organic chemical vapor deposition (MOCVD) apparatus and, more particularly, to an MOCVD apparatus capable of preventing damage to an internal component thereof to thus have enhanced operational reliability.

2. Description of the Related Art

Due to the growing demand for smaller semiconductor devices, the development of high efficiency, high output LEDs, and the like, in various industrial fields, has led to a requirement for a metal-organic chemical vapor deposition (MOCVD) device apparatus allowing for semiconductor devices to be mass-produced without degradations in the quality and performance thereof.

A general MODVD apparatus includes a reaction chamber having an interior space having a certain volume, a susceptor installed in the interior space of the reaction chamber and allowing a wafer to be mounted thereon as a deposition object, a heating unit provided adjacently to the susceptor and applying a predetermined amount of heat, and also has a gas inlet through which a reactive gas is supplied to the chamber.

In particular, the susceptor is generally configured to face upwardly to allow a wafer to be mounted on an upper surface thereof and be disposed in a lower portion in the reactive chamber such that it faces the gas inlet. Thus, after film formation, the reaction chamber is open and the wafer is replaced.

Meanwhile, in order to maintain a vacuum state, a chamber main body and a chamber cover of the reaction chamber are tightly attached to one another through an O-ring, or the like, requiring a relatively large amount of force to open the chamber, and this causes a generation of vibrations in the chamber when the chamber main body and the chamber cover are separated.

Such vibrations may damage a cover member made of quartz mounted on an interior side of the chamber cover, frequently requiring repairs, to thereby degrade productivity and operational reliability.

In addition, since the cover member is provided in an upper portion within the reaction chamber, a dummy coating formed according to parasitic deposition may cling to the cover member, and thus, in order to minimize a dummy coating formation and prevent influence thereof on growth conditions, the cover member is cooled during a growth operation.

Thus, the cover member is continuously exposed to stress according to temperature gradient and stress due to a difference between a thermal expansion coefficient thereof and that of a dummy coating material, so as to be readily damaged, resulting in a shortened replacement period whereby repair costs may be increased and the replacement of the entirety thereof is a necessity.

### SUMMARY OF THE INVENTION

An aspect of the present invention provides a metal-organic chemical vapor deposition (MOCVD) apparatus in which a cover member is prevented from being damaged by altering a structure thereof, thus providing enhanced reliability.

According to an aspect of the present invention, there is provided a metal-organic chemical vapor deposition (MOCVD) apparatus including: a reaction chamber including a chamber main body forming an interior space having a certain volume and a chamber cover hermetically sealing the chamber main body to maintain air-tightness; a susceptor rotatably provided within the chamber main body and having one or more accommodation portions formed in an upper surface thereto to accommodate wafers; a cover member detachably provided on an interior surface of the chamber cover, forming a reaction space between the cover member and the susceptor, and formed by coupling a plurality of section members; and a gas supply unit supplying a reactive gas to the reaction space to allow the reactive gas to flow between the susceptor and the cover member.

The cover member may have a shape corresponding to the susceptor and have a central hole allowing the gas supply unit disposed at the center of the chamber cover to be coupled therethrough.

The cover member may have a structure in which a central region thereof is spaced apart from the chamber cover by a certain interval and the interval between the cover member and the chamber cover may be gradually reduced in a direction toward circumferential edges along a diameter thereof.

The cover member may be divided along the diameter thereof.

The cover member may be divided into annular section members having different diameters by concentric circles.

The respective section members of the cover member divided by the concentric circles may have a step along a divided plane.

The cover member may be spaced apart from the chamber cover by a certain distance to form a cooling space between an upper surface of the cover member and a lower interior surface of the chamber cover, into which a refrigerant is injected.

The MOCVD apparatus may further include a refrigerant supply unit supplying a refrigerant to a space between the chamber cover and the cover member to allow the refrigerant to flow therein.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically illustrating a metal-organic chemical vapor deposition (MOCVD) apparatus according to an embodiment of the present invention;

FIG. 2 is a cross-sectional view illustrating the MOCVD apparatus of FIG. 1 in an open state;

FIG. 3 is a cross-sectional view schematically showing a cover member provided on a chamber cover in the

MOCVD apparatus of FIG. 1;

FIG. 4 is a bottom view schematically showing the cover member of FIG. 3;

FIGS. 5 through 9 are views illustrating various embodiments of the cover member divided into section members;

FIGS. 10A and 10B are cross-sectional views of the cover member of FIGS. 8 and 9; and

FIGS. 11A to 11D are views schematically illustrating a connection unit connecting the section members of the cover member of FIGS. 5 to 9.

### DETAILED DESCRIPTION OF THE PREFERRED EMBODIMENT

A metal-organic chemical vapor deposition (MOCVD) apparatus according to embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like components.

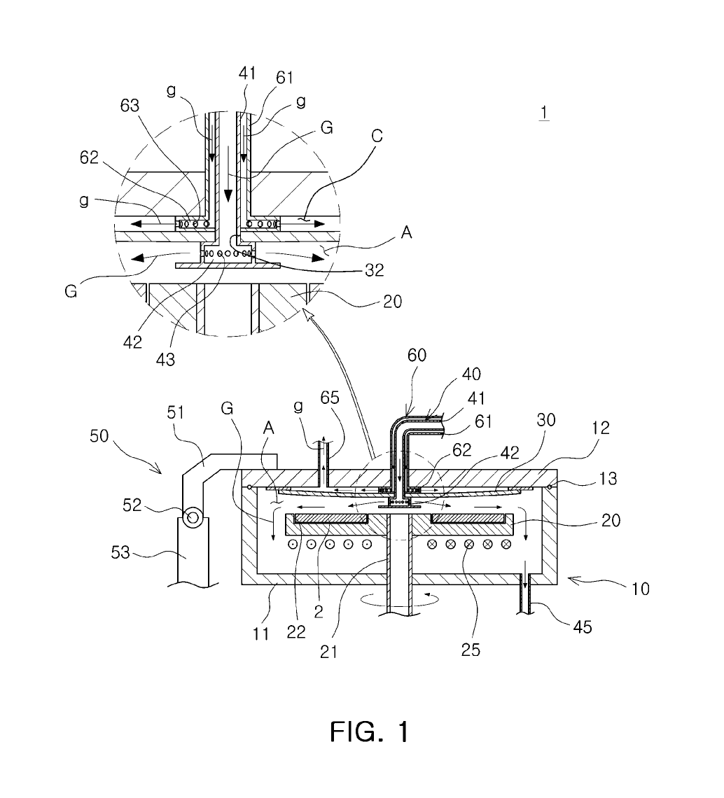

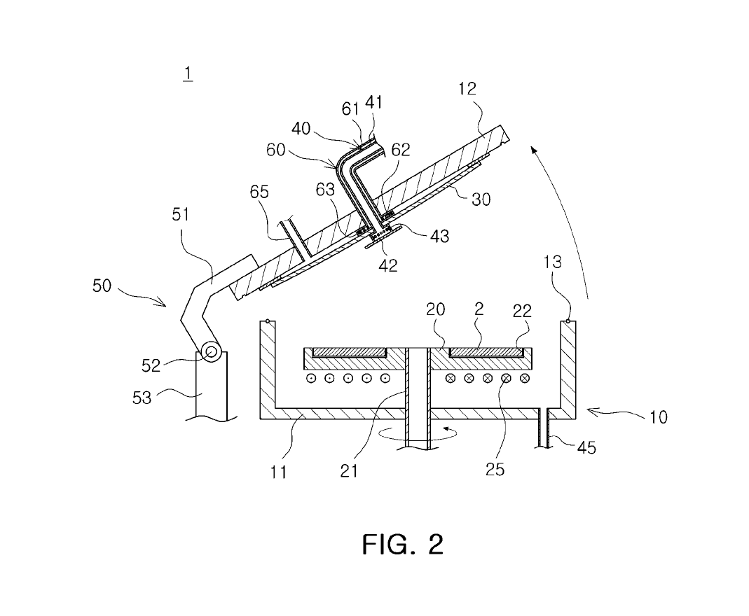

The MOCVD apparatus according to an embodiment of the present invention will be described with reference to FIGS. 1 and 2.

FIG. 1 is a cross-sectional view schematically illustrating a metal-organic chemical vapor deposition (MOCVD) apparatus according to an embodiment of the present invention. FIG. 2 is a cross-sectional view illustrating an open state of the MOCVD apparatus of FIG. 1.

Referring to FIGS. 1 and 2, the MOCVD apparatus 1 according to an embodiment of the present invention may include a reaction chamber 10, a susceptor 20, a cover member 30, and a gas supply unit 40.

The reaction chamber 10 includes a chamber main body 11 forming an interior space having a certain volume and a chamber cover 12 hermetically sealing the chamber main body 11 to maintain air-tightness. The chamber cover 12 is opened and closed with respect to the chamber main body 11. In order to ensure air-tightness, a sealing member such as an O-ring 13 may be provided on an upper end portion of the chamber main body 11 coupled to the chamber cover 12. The reaction chamber 10 may be made of a metal having excellent abrasion resistance and corrosion resistance.

Also, a cover rotating unit 50 may be provided on one side of the reaction chamber 10 to rotate any one of the chamber main body 11 and the chamber cover 12 to separate or join or combine them. The cover rotating unit 50 may include a rotatable arm 51 having one end connected to the chamber cover 12, and a fixed arm 53 having an upper end connected to the rotatable arm 51 by a hinge shaft 52.

Here, it is illustrated that the rotatable arm 51 is connected to the chamber cover 12 to rotate the chamber cover 12 with respect to the chamber main body 11 to separate the chamber cover 12 from the chamber main body 11 or join or combine the chamber cover 12 to the chamber main body 11, but the present invention is not limited thereto.

The susceptor 20 is disposed within the chamber main body 11 and rotatable via a rotary shaft 21 disposed in a central portion of the chamber main body 11. The susceptor 20 includes one or more downwardly recessed disk-type accommodation portions 22 formed to accommodate a wafer 2 as a deposition subject therein.

A heating unit 25 is provided below the susceptor 20 to provide radiant heat to the susceptor to heat the wafer 2 loaded on the susceptor 20. The heating unit 25, a type of heat transfer member generating heat when power is applied thereto, is disposed in a region corresponding to the pocket 22.

The cover member 30 has an overall circular shape corresponding to the chamber cover 12 and is detachably provided on a lower surface, i.e., an interior surface, of the chamber cover 12 constituting an upper interior surface of the reaction chamber 10, forming a reaction space A with the susceptor 20. In particular, the cover member 30 is divided into a plurality of section members 31. In other words, the section members 31 are coupled to from the cover member 30. A detailed structure of the cover member 31 will be described later.

The gas supply unit 40 supplies a reactive gas G to a reaction space A to allow the reactive gas G to flow between the susceptor 20 and the cover member 30 opposed to each other. In detail, the gas supply unit 40 is disposed at the center of the chamber cover 12 and supplies the reactive gas G such that the reactive gas G flows from the center of the reaction chamber 10 toward an exterior circumference.

The gas supply unit 40 includes a gas supply pipe 41 formed to penetrate the center of the chamber cover 12 and the cover member 30 to extend to the interior of the reaction chamber 10 and a gas jet nozzle 42 connected to an end of the gas supply pipe 41. The gas jet nozzle 42 is connected to an end of the gas supply pipe 41. The gas jet nozzle 42 includes a plurality of nozzle holes 43 for jetting the reactive gas G supplied from the gas supply pipe 41 to the interior of the reaction chamber 10.

The reactive gas G introduced into the reaction chamber 10 through the gas supply unit 40 flows from the center of the reaction chamber 10 to the exterior circumference along the reaction space A between the susceptor 20 and the cover member 30 and expelled to the outside through a gas emission unit 45.

Accordingly, as shown in FIG. 2, as illustrated in FIG. 2, the cover rotating unit 50 rotates the chamber cover 12 connected to the rotatable arm 51 with respect to the fixed chamber main body 11 in a counterclockwise direction through an opening operation, thus opening the susceptor 20 provided in the chamber main body 11.

In this state, the wafers 2 as deposition targets are insertedly disposed in each of the plurality of accommodation portions 22 formed on the susceptor 20 or a deposition-completed wafer 2 is replaced with a new wafer.

In addition, a cleaning operation may be performed on the surface of the susceptor 20 and the accommodation portions 22 exposed to the reaction space A, dummy coating clinging to the surface of the cover member 30 exposed to the reaction space A may be removed, or a defective cover member 30 may be replaced.

In particular, in the case of the cover member 30, in order to easily prevent the cover member 30 from being damaged and facilitate maintenance due to a defect, the cover member 30 includes a plurality of section members 31.

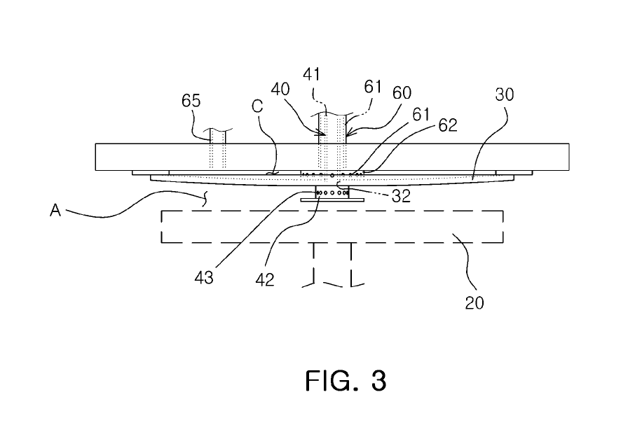

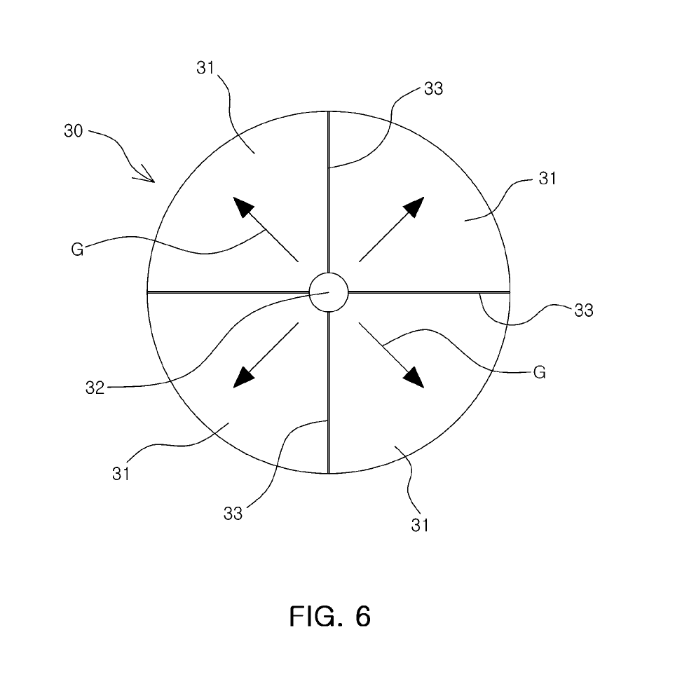

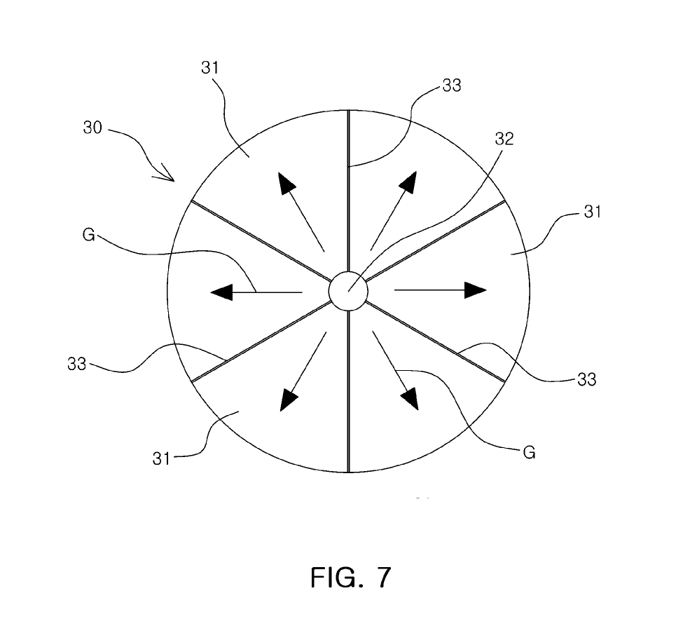

The cover member 30 will be described in detail with reference to FIGS. 3 through 11.

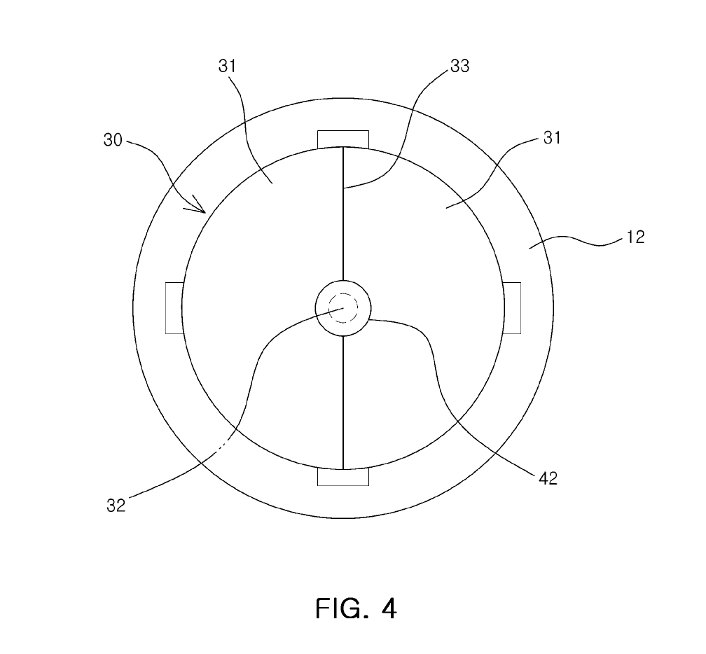

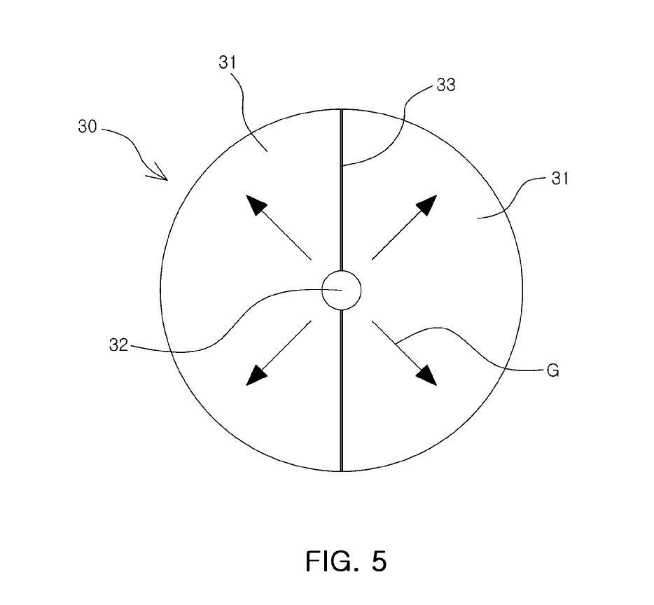

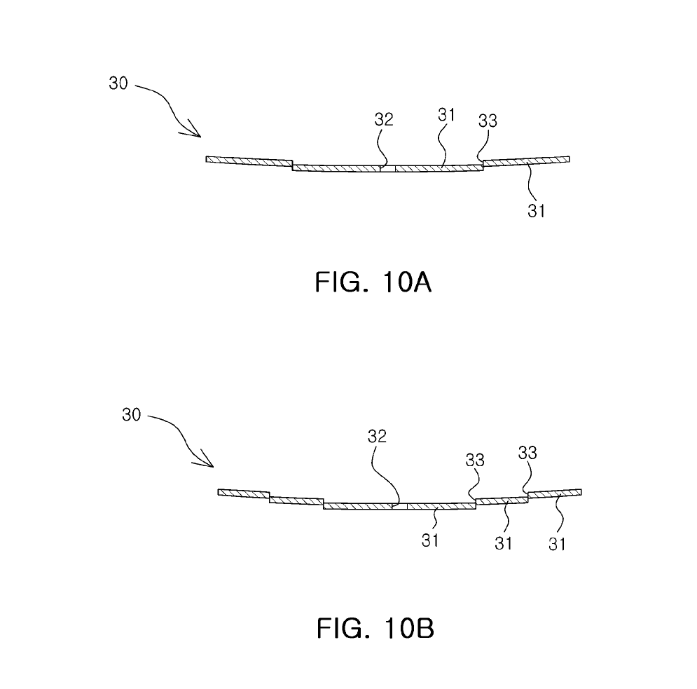

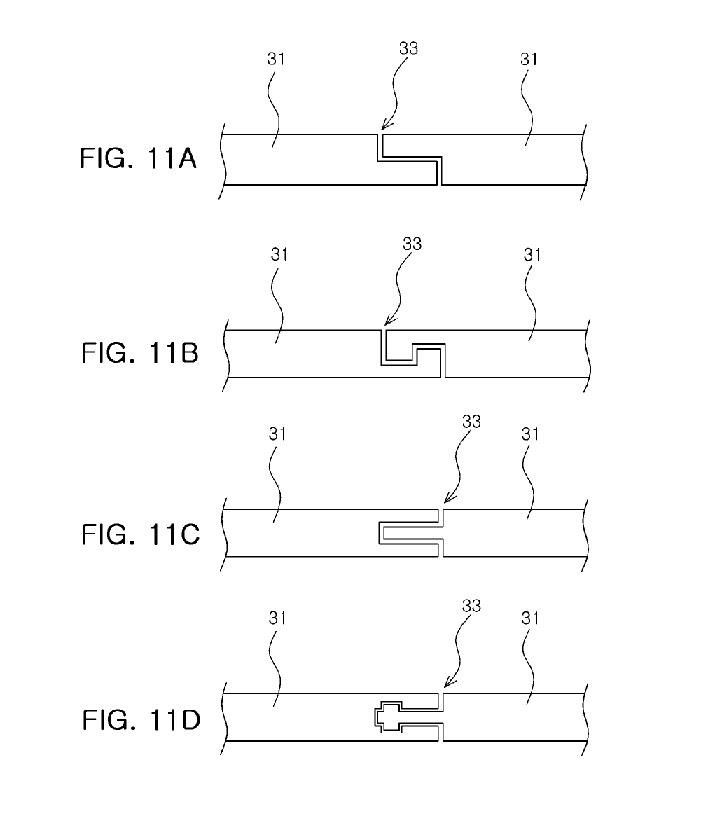

FIG. 3 is a cross-sectional view schematically showing a cover member provided on a chamber cover in the MOCVD apparatus of FIG. 1. FIG. 4 is a bottom view schematically showing the cover member of FIG. 3. FIGS. 5 through 9 are views illustrating various embodiments of the cover member divided into section members. FIGS. 10A and 10B are cross-sectional views of the cover member of FIGS. and 9; and FIGS. 11A to 11D are views schematically illustrating a connection unit connecting the section members of the cover member of FIGS. 5 to 9.

As illustrated in FIGS. 3 and 4, the cover member 30 may have a shape corresponding to the chamber cover 12 and has a diameter equal to or greater than that of the susceptor 20. The cover member 30 is disposed to face the susceptor 20 to form the reaction space A therebetween, and is detachably attached to a lower surface of the chamber cover 12. Here, the cover member 30 includes a central hole 32 formed in a penetrative manner therein, and the gas supply unit 40 disposed at the center of the chamber cover 12 penetrates the central hole 32 so as to be coupled to the chamber cover 12.

The cover member 30 serves to protect the chamber cover 12 against dummy coating generated during a deposition operation. Namely, the cover member 30 prevents the reactive gas G forming a high temperature atmosphere from coming into contact with a lower surface of the chamber cover 12 to thus eliminate the formation of a dummy coating thereon.

Here, in order to minimize a generation of dummy coating on the surface of the cover member 30, the cover member 30 is required to be in a cooled state. To this end, the lower surface of the chamber cover 12 forming an upper interior surface of the reaction chamber 10 is spaced apart from the upper surface of the cover member 30 by a certain distance to form a cooling space C for injecting a refrigerant g such as a cooling gas therebetween.

As illustrated, the cover member 30 is gently sloped toward the edges of the cover member 30 such that the edges of the cover member 30 are in contact with the chamber cover 12 while a central region of the cover member 30 is spaced apart from the chamber cover 12, thus forming the sealed cooling space C. Namely, the cover member 30 has a structure in which an interval between the central region thereof and the chamber cover 12 is gradually reduced in a direction toward the circumferential edges along a diameter in a state in which the central region of the cover member 30 is spaced apart from the chamber cover 12 by a certain interval. However, the present invention is not limited thereto and the cover member 30 may have a flat plate structure and include a sealing member along the edge region to form a cooling space.

A refrigerant supply unit 60 for supplying the refrigerant g to the cooling space C to allow the refrigerant g to flow between the chamber cover 12 and the cover member 30 is provided between the chamber cover 12 and the cover member 30. In detail, like the gas supply unit 40, the refrigerant supply unit 60 is disposed at the center of the chamber cover 12 to supply the refrigerant g to form a flow that the refrigerant g flows toward the edges of the cover member 30.

The refrigerant supply unit 60 includes a refrigerant supply pipe 61 extending to the cooling space C through the center of the chamber cover 12 and a refrigerant jet nozzle 62 connected to an end of the refrigerant supply pipe 61. The refrigerant jet nozzle 62 includes a plurality of nozzle holes 63 for jetting the refrigerant g supplied from the refrigerant supply pipe 61 to the cooling space C. The refrigerant g introduced into the cooling space C cools the cover member 30 and subsequently moves to a reservoir (not shown) through a refrigerant discharge unit 65 provided on the chamber cover 12.

Thus, by lowering a temperature of the cover member relatively, a generation of dummy coating can be minimized, and in addition, damage to the cover member 30 due to stress according to a temperature gradient between the lower end portion of the cover member exposed to a high temperature atmosphere and the upper end portion of the cover member exposed to a relatively low temperature atmosphere as in the related art structure in which the cover member is in contact with the chamber cover 12 to be integrated therewith can be prevented.

In particular, in an embodiment of the present invention, in order to prevent the cover member 30 from being damaged due to stress according to the temperature gradient and stress due to a difference between a thermal expansion coefficient of the cover member 30 and that of a dummy coating material, the cover member 30 is divided into a plurality of section members 31 and the plurality of section members 31 are coupled.

As illustrated in FIGS. 5 through 7, the cover member 30 may include a plurality of section members 31 divided along the diameter, and the respective section members 31 may be coupled by a connection unit 33 connecting the central through hole 32 to the exterior edges. In this case, the respective section members 31 have the same size and shape, and since the neighboring section members 31 are radially provided in a direction in which the reactive gas G flows from the center of the cover member 30 toward the exterior circumference, they do not interfere with the flow of the reactive gas G, maintaining a stable flow of the reactive gas G, and thus, a uniform epitaxial layer can be obtained.

Also, since the section members 31 have a structure in which areas thereof are increased from the center toward the exterior circumference, a generation of cracks in the central region in which a great deal of thermal stress is relatively generated can be prevented.

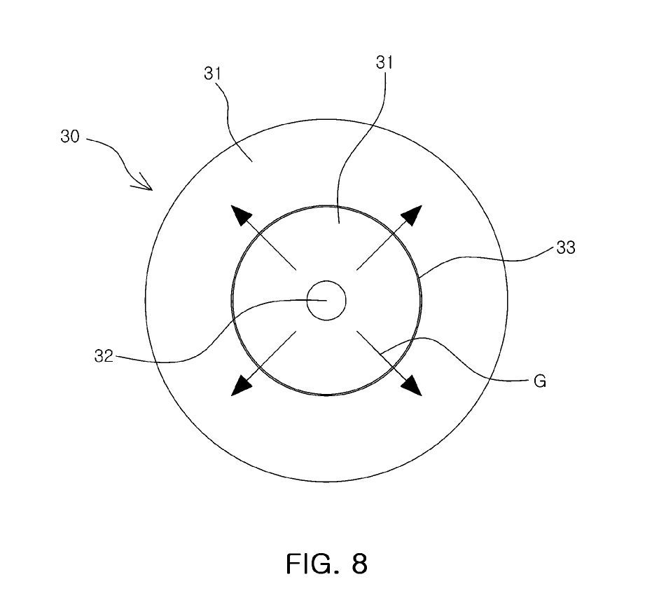

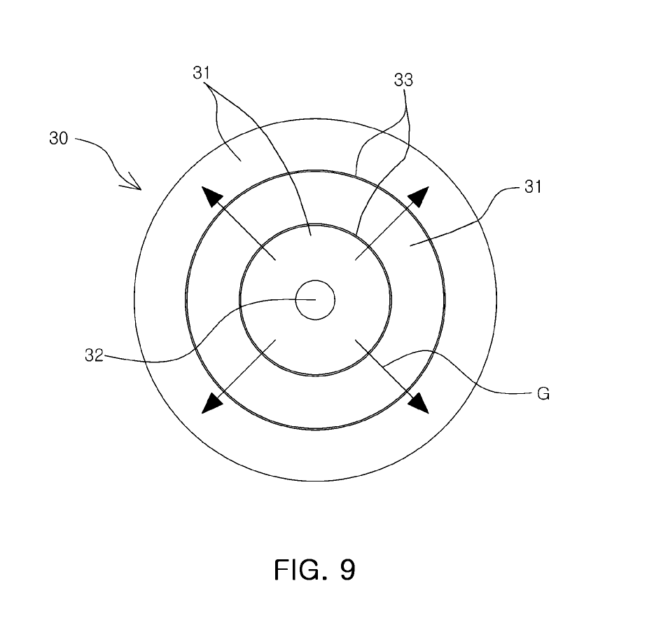

Meanwhile, as illustrated in FIGS. 8 and 9, the cover member 30 may be divided along a concentric circle to have different diameters and being perpendicular to a flow of the reactive gas G, so the respective section members 31 may have an annular shape. In this case, the respective section members 31 have the same shape but different sizes, and have a structure in which a radius thereof is increased from the center toward the edges.

As illustrated in FIG. 10, when the cover member 30 is divided to be perpendicular to the flow of the reactive gas G so the respective section members 31 have an annular shape, the connection unit 33 connecting the respective section members 31 is provided along an interior circumferential surface and an exterior circumferential surface of the section members 31 such that it is perpendicular to the flow of the reactive gas G. Thus, the connection unit 33 has a step along the mutually facing divided planes between the connection unit 33 such that a distance between the cover member 30 and the chamber cover 120 is gradually reduced in a direction toward the edges of the cover member 30, thus not interfering with the flow of the reactive gas G.

As illustrated in FIG. 11, the connection unit 33 may have a structure in which the section members 31 are engaged with each other so as to be stably connected and firmly coupled. In addition, a gap is formed between the connection units 33 to thereby alleviate thermal stress to prevent a generation of cracks although the section members expand and contract repeatedly according to a temperature gradient.

The cover member 30 is made of a material having excellent heat resistance. Preferably, the cover member 30 is made of quartz or SiC-coated graphite, but the present invention is not limited thereto.

In this manner, the cover member is divided into a plurality of section members, rather than the integral structure as in the related art, and the section members are coupled, whereby a generation of cracks due to stress according to the temperature gradient and stress generated between the cover member and a dummy coating material can be prevented, and if cracks are generated in a portion, only the section member of the corresponding region may be replaced, thus facilitating maintenance and saving costs.

As set forth above, according to embodiments of the invention, stress applied to the cover member is reduced to prevent damage to the cover member, thus enhancing operational reliability and lengthening a replacement period.

In addition, if a portion of the cover member is damaged, only the section member corresponding to the damaged portion is replaced, facilitating maintenance and reducing costs for replacement to thus save costs.

While the present invention has been shown and described in connection with the embodiments, it will be apparent to those skilled in the art that modifications and variations can be made without departing from the spirit and scope of the invention as defined by the appended claims.

1. A metal-organic chemical vapor deposition (MOCVD) apparatus comprising:
a reaction chamber including a chamber main body forming an interior space having a certain volume and a chamber cover hermetically sealing the chamber main body to maintain air-tightness;
a susceptor rotatably provided within the chamber main body and having one or more accommodation portions formed in an upper surface thereto to accommodate wafers;
a cover member detachably provided on an interior surface of the chamber cover, forming a reaction space between the cover member and the susceptor, and formed by coupling a plurality of section members; and
a gas supply unit supplying a reactive gas to the reaction space to allow the reactive gas to flow between the susceptor and the cover member.

2. The MOCVD apparatus of claim 1, wherein the cover member has a shape corresponding to the susceptor and has a central hole allowing the gas supply unit disposed at the center of the chamber cover to be coupled therethrough.

3. The MOCVD apparatus of claim 1, wherein the cover member has a structure in which a central region thereof is spaced apart from the chamber cover by a certain interval and the interval between the cover member and the chamber cover is gradually reduced in a direction toward circumferential edges along a diameter thereof.

4. The MOCVD apparatus of claim 1, wherein the cover member is divided along the diameter thereof.

5. The MOCVD apparatus of claim 1, wherein the cover member is divided into annular section members having different diameters by concentric circles.

6. The MOCVD apparatus of claim 5, wherein the respective section members of the cover member divided by the concentric circles have a step along a divided plane.

7. The MOCVD apparatus of claim 1, wherein the cover member is spaced apart from the chamber cover by a certain distance to form a cooling space between an upper surface of the cover member and a lower interior surface of the chamber cover, into which a refrigerant is injected.

8. The MOCVD apparatus of claim 7, further comprising a refrigerant supply unit supplying a refrigerant to a space between the chamber cover and the cover member to allow the refrigerant to flow therein.
